(19) United States
(12) Patent Application Publication
(10) Pub. No.: US 2018/0352619 A1
(43) Pub. Date: Dec. 6, 2018

(54) METHOD AND ICT DEVICE FOR INSPECTING MODULES OF A LIGHTING DEVICE CONTAINING AT LEAST TWO LEDs

(71) Applicant: ZKW GROUP GMBH, Wieselburg (AT)

(72) Inventors: Emanuel WEBER, Baden (AT); Stefan ESTERLE, Grub (AT)

(21) Appl. No.: 16/058,367

(22) Filed: Aug. 8, 2018

Related U.S. Application Data
(63) Continuation-in-part of application No. PCT/AT2017/060020, filed on Feb. 6, 2017.

(30) Foreign Application Priority Data
Feb. 11, 2016 (AT) A 50087/2016

(51) Int. Cl. H05B 33/08; G01R 31/26

(52) U.S. Cl. CPC H05B 33/089; G01R 31/2635

(57) ABSTRACT

A method for inspecting LED modules of a lighting device containing at least two LEDs is provided: A pair of LEDs of a module is selected, the LEDs are connected to one another optically, preferably via a light guide, one LED is connected to a power source and the other LED is connected to an electrical measuring device, the two LEDs of a pair are connected together optically via an optical waveguide, one LED is energised with a predefined current strength and the physical change produced in the other LED is measured, and then the energising and measuring at the two LEDs are swapped, and the module is identified as faulty if the measured value lies outside a definable range in at least one measurement. An ICT device for performing the method includes an ICT adapter means including at least one optical waveguide for the optical connection of the LEDs.

### CROSS-REFERENCE TO RELATED APPLICATIONS

This is a continuation-in-part of International Application No. PCT/AT2017/060020, filed Feb. 6, 2017, which claims priority to Austrian Patent Application No. A 50087/2016, filed Feb. 11, 2016. The applications are incorporated by reference herein.

### TECHNICAL FIELD

The invention relates to a method for inspecting LED modules of a lighting device containing at least two LEDs, in which at least one pair of LEDs of a module is selected, one of the two LEDs of the pair is connected to at least one power source and the other of the two LEDs is connected to at least one electrical measuring device, one of the two LEDs is energised with a predefined current strength and the physical change produced in the other of the two LEDs is measured, and then the energising and measuring at the two LEDs of the pair are swapped and the module is identified as faulty if the value determined by means of the measuring device lies outside a definable range in at least one measurement.

The invention also relates to an ICT device for inspecting modules of a lighting device containing at least two LEDs by means of a method according to the invention, said device comprising ICT adapter means, comprising at least one power source, and comprising at least one electrical measuring device, wherein the ICT adapter means has contact-making means for contacting measurement points and/or solder points of the LEDs.

### BACKGROUND

LED light modules, specifically in the automotive field, have to undergo a functionality diagnosis before they can be used. This means that, when functionality is inspected after a printed circuit board has been equipped with LEDs and optionally other components, a query must be performed, on which basis the status of the individual LEDs in the light module is provided. Individual light modules consist in many cases of a plurality of LEDs arranged in a string. The diagnosis of such LED strings is performed by means of a current-voltage measurement in accordance with the prior art. If the measured voltage rises above or drops below a certain limit value, a malfunction is diagnosed and the necessary measures are performed; for example, the corresponding module is marked as rejected.

Diagnosis measurements of this kind, however, which are based merely on the measurement of the electrical parameters of the LEDs, are reflective only of the electrical functionality. Should an error occur in the optical region of the light module, this cannot be diagnosed and, accordingly, it is also not possible to eliminate a faulty module or to label it as defective. A diagnosis possibility according to the prior art which assesses the actual optical function of the light module is the optical inspection of LEDs in an ICT (in-circuit test) or in an EOL (end-of-line) test after manufacture. Here, either glass fibre modules, which are connected to an external photodetector, or camera-based systems are used. The disadvantage of these systems lies in the high acquisition costs and the only limited diagnosis possibility, since in these systems only a works/doesn't work inspection is usually performed.

Document U.S. Pat. No. 4,797,609 A presents a device for inspecting an LED array having typically a few thousand LEDs used for the exposure of a photographic film in the sense of the production of high-resolution images for example for aerial camera. The LEDs are controlled here digitally, for example by a satellite camera.

In order to inspect these LEDs in respect of their function, in particular their brightness value, one LED is selected by means of an electronic switch and is actuated with a current, such that the LED lights up. In so doing, a current is produced in an adjacent LED, which is seemingly lit up without further aids by diffuse light of the actuated LED, and said current is measured. Understandably, this known inspection method presupposes a close proximity of the LEDs to be inspected, however this is not generally provided in light modules with specific arrays.

One object of the invention is providing a method which allows an economical and reliable inspection of the LEDs of an LED light module. A further object of the invention is providing an ICT device suitable for carrying out a corresponding method, which ICT device can be produced without great effort.

### DETAILED DESCRIPTION

In order to solve the stated problems, the invention provides a method of the kind described at the outset, in which, in accordance with the invention, the two LEDs of a pair are connected to one another optically via an optical waveguide.

A preferred embodiment of the invention is characterised in that if LED modules have more than two LEDs the method steps are applied to all possible pairs of LEDs.

Advantageously if LED modules have more than one pair of LEDs two or more optical waveguides are used for the optical connection of in each case two LEDs.

It is also preferred if an ICT adapter is used to connect LEDs arranged on a printed circuit board to the at least one power source and to the at least one measuring device so as to contact measurement points and/or solder points of the LEDs and so as to produce the optical connection via an optical waveguide.

A further preferred embodiment of the invention provides that the two ends of the optical waveguide are brought in a centred manner into the vicinity of the electro-optical active regions of the two LEDs of the at least one pair of LEDs.

It is particularly advantageous if current and/or voltage are/is measured by means of the measuring device.

The object is also achieved with an ICT device of the above-mentioned kind, in which the ICT adapter means has at least one optical waveguide for the optical connection of in each case two LEDs.

It is advantageous here if the at least one optical waveguide is formed as an optical fibre line.

Another preferred embodiment provides that the at least one optical waveguide is formed as a light-guiding U-shaped rod.

It can also be advantageous if two or more optical waveguides are provided for LEDs sitting on a printed circuit board.

A preferred embodiment provides that the measuring device is a current/voltage measuring system.

The invention together with further advantages will be explained in greater detail hereinafter on the basis of exemplary embodiments, which are shown in the drawings. The drawings show:

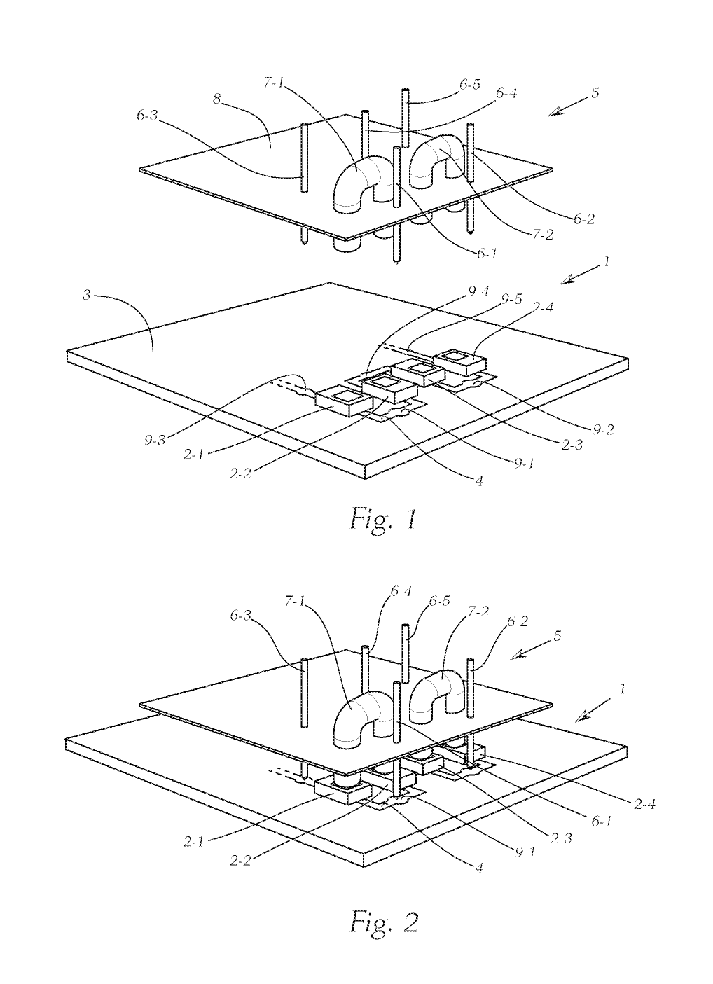

FIG. 1 a perspective view of an LED module, inclusive of printed circuit board and, arranged thereabove, an ICT adapter of an ICT measuring device according to the invention,

FIG. 2 a view as in FIG. 1, but with an ICT adapter lowered onto the printed circuit board and contacted therewith,

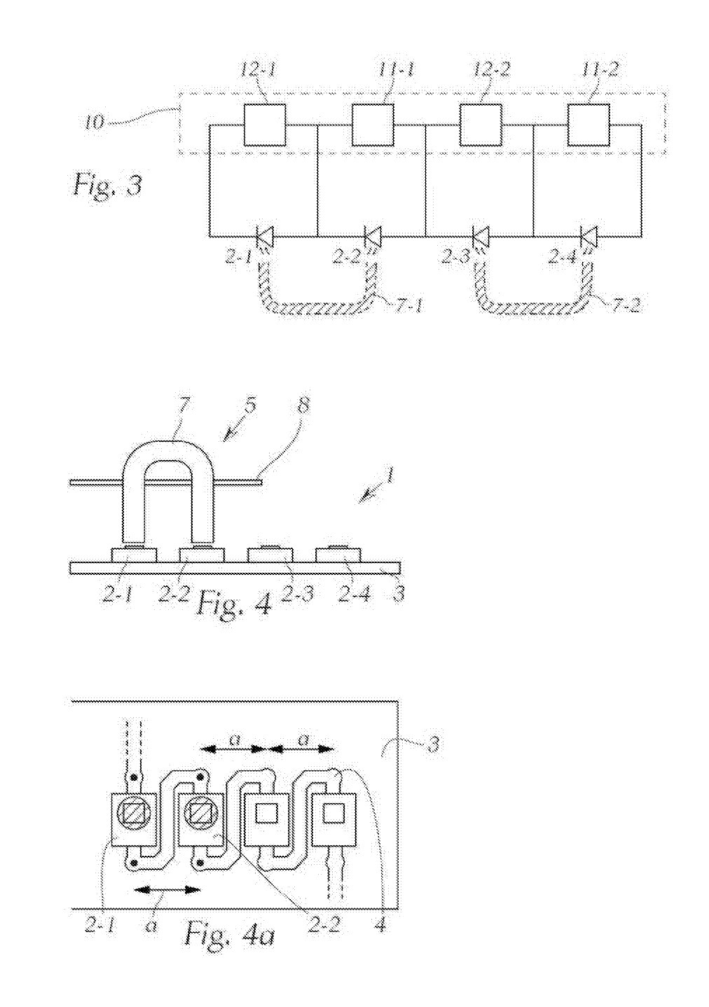

FIG. 3 shows the inspection of four LEDs connected in series in the form of a schematic circuit diagram,

FIG. 4 to 6 and FIG. 4a to 6a each show, in side views and plan views respectively, three steps for inspecting a module comprising four LEDs.

FIG. 1 shows an LED module 1, which in this example has four LEDs 2-1, 2-2, 2-3 and 2-4, which are arranged on a printed circuit board 3 and are connected to one another via conductive tracks 4, wherein the LEDs are generally connected in series, as is the case shown here. An LED module of this kind can be used in particular in a vehicle headlamp.

As already explained further above, LED modules have to be inspected for correct functioning prior to use. To this end, what is known as an ICT (in-circuit test) or a corresponding ICT device having suitable adapter means is used, wherein an ICT adapter 5 suitable for carrying out the method according to the invention is shown in FIG. 1.

The ICT adapter 5 shown by way of example in this case has five measuring pins 6-1 to 6-5 and two U-shaped light guides 7-1, 7-2 with (in the drawing) downwardly directed, usually flat end faces for light entry and light exit.

The measuring pins 6-1 to 6-5 and the light guides 7-1, 7-2 are fastened to and arranged on a carrier 8 (shown schematically) in such a way that in each case two LEDs 2-1, 2-2 or 2-3, 2-4 can be connected to one another optically with the aid of the light guides 7-1, 7-2 if the ICT adapter 5 is brought into contact with the LED module 1, with reference being made in this respect to the illustration of FIG. 2. In this contacted position the measuring pins 6-1 to 6-5 engage with measurement points 9-1 to 9-5 of the conductive tracks 4. In order to ensure the desired electrical contact, the measurement points must be freed of solder resist, which is provided in any case. The measuring pins 6-1 to 6-5 are of course made of conductive material and are connected to at least one power source and to at least one electrical measuring device in the manner described further below.

In order to inspect the LED module 1, the ICT adapter 5 is pressed against the module 1 with a certain force, which is sufficient to ensure reliable electrical contact. Here, the end faces of the U-shaped light guides 7-1, 7-2 do not necessarily have to come into physical contact with the LEDs, but instead shall be centred in the vicinity of the electro-optically active regions of the LEDs.

Now with reference to FIG. 3, it shall be explained in greater detail that, in order to carry out the method according to the invention, proceeding from the contacted position of the LED module 1 and the ICT adapter, in each case one of the two LEDs connected optically via a light guide is used as light source and the second is used as photodetector. The power supply and the measurement are realised via the measuring pins 6-1 to 6-5.

The invention is based on the concept that optical paths, in the shown example the U-shaped light guides, are arranged between the individual LEDs for the introduction of light from one LED to another during the function test. One LED is used here as light source, and at the other a voltage proportional to the luminous flux is established, as is the case in a photodiode. One LED is thus operated in the forward direction and photons are produced in the PN junction of the semiconductor. On the other hand, at the other LED, which is not actively energised, photons arriving at the PN junction are converted into electrical energy.

FIG. 3 shows the series connection of four LEDs 2-1, 2-2, 2-3 and 2-4 of a module, for example of the module 1 of FIGS. 1 and 2, wherein light guides 7-1 and 7-2 brought into position are shown schematically between the LEDs 1-2 and 2-2 on the one hand and 2-3 and 2-4 on the other hand.

The connections of the LEDs can be connected temporarily to an inspection device 10 (shown schematically) via the measuring pins, the measurement points and the conductive tracks, wherein said inspection device also has switch means (not shown) so as to connect the accordingly selected LEDs also to at least one electrical measuring device. The inspection device 10 will generally also have a microcomputer, which controls the entire sequence of energisation of the LEDs, the measurement, and the movement of the ICT adapter.

In the state shown in FIG. 3, the LEDs 2-2 and 2-4 are connected to power sources 11-1 and 11-2 and the LEDs 2-1 and 2-3 are connected to electrical measuring devices 12-2 and 12-2, which are preferably designed or suitable for measuring voltage or current. Quite generally, physical changes to the LEDs can be measured, for example the capacitance, which is dependent on the strength and/or duration of the incidence of light.

In principle, the method according to the invention is performed such that at least one pair of LEDs of a module is selected, in the shown example the LED pairs 2-1, 2-2 and 2-3, 2-4, and then the two LEDs of this pair are connected to one another optically via an optical waveguide, here the light guides 7-1, 7-2.

One of the two LEDs of the pair, here the LEDs 2-2, 2-4, is then connected to at least one power source 11-1, 11-2, and the other of the two LEDs 2-1, 2-3 is connected to at least one electrical measuring device 12-1, 12-2.

In each case one of the two LEDs 2-2, 2-4 is now energised with a predefined current strength and the physical change produced in the other of the two LEDs 2-1, 2-3 is measured. The energising and measuring at the two LEDs of the pair are then swapped, and the module is identified as faulty if the value determined by means of the measuring device or measuring devices, for example a measured voltage, lies outside a definable range in at least one measurement. The term “range” is intended to comprise any ranges, even upwardly or downwardly open ranges. For example, the voltage at the non-energised LED of a pair can be measured, and the module can then be identified as faulty if the measured voltage value lies below a defined voltage level. The range can also be selected to be very narrow, and therefore the measured value has to correspond practically to this value within the measurement accuracy of the particular case in question, otherwise a module is considered to be faulty.

A measurement process is shown in greater detail with reference to the example of FIG. 4 to 6 and FIG. 4a to 6a.

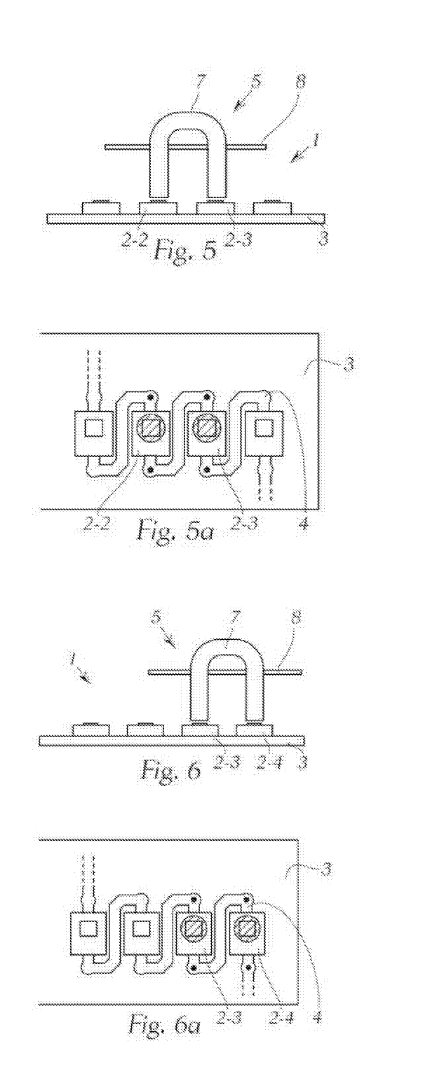

The ICT adapter 5 is displaceable so as to require just one light guide 7, and a measuring device and a power source for an LED module 1 having more than two LEDs (four LEDs 2-1, 2-2, 2-3 and 2-4 are again shown). Accordingly, four measuring pins are used here, which are not shown in this drawing either, similarly to the measuring device and the power source. Here, as can be seen, the ICT adapter 5 with the light guide 7 and the measuring pins is moved on from one LED pair (in FIGS. 4 and 4a the LEDs 2-1 and 2-2) to the next (in FIGS. 5 and 5a the LEDs 2-2, 2-3 and in FIGS. 6 and 6a the LEDs 2-3, 2-4). The measurement points explained in greater detail above on the printed circuit board 3 and the LEDs 2-1, 2-2, 2-3 and 2-4 of the LED module 1 are advantageously arranged in such a way, or the spacing therebetween (see the arrows a in FIG. 4a) is such that it is possible to carry out the method for the four shown LEDs of the LED module with merely four measuring pins and one light guide. The hatched areas in FIGS. 4a, 5a and 6a show the selected LED pairs, and the dots on the conductive tracks show the contacting points of the measuring pins used in those cases:

With appropriate design of the conductive tracks, it is also possible to use merely three measuring pins, since the circuitry (as visible in FIG. 3) allows one contact to be used jointly for the measuring device and the power supply. For example, one contact between two LEDs could thus be contacted with a measuring pin, and outside the ICT adapter 5 could be divided between the respective measuring devices or power sources.

However, it is also possible to configure the arrangement of the LEDs and the associated conductive tracks such that just one light guide, but a plurality of measuring pins are required. A case of this kind exists if the placement of the printed circuit board does not allow a course of the conductive tracks as shown in the drawings. It is also possible to use merely three of four measuring pins, but a plurality of light guides, since, similarly, in some circumstances the LEDs in the LED module cannot be arranged with a regular spacing from one another for photometric reasons.

It can be seen that the method sketched in FIG. 4 to 6a is particularly advantageous, since the component cost both in the adapter 5 and in the inspection device 10 can be kept low.

The fact that each LED is used both as light source and as photodetector of course leads to a particularly high level of reliability of the inspection with increased error detection rate.

That which is claimed is:

1. A method for inspecting LED modules (1) of a lighting device containing at least two LEDs (2-1 . . . 2-4), the method comprising:
selecting at least one pair (2-1, 2-2; 2-3, 2-4) of LEDs of the module (1);
connecting one (2-2; 2-4) of the two LEDs of the pair to at least one power source (11-1; 11-2) and connecting the other (2-1; 2-3) of the two LEDs to at least one electrical measuring device (12-1; 12-2);
energizing one of the two LEDs with a predefined current strength and measuring the physical change produced in the other of the two LEDs; and then
swapping the energizing and measuring at the two LEDs of the pair,
wherein two LEDs (2-1; 2-2) of the at least one pair are connected to one another optically via an optical waveguide (7-1; 7-2) and wherein the module is identified as faulty if the value determined by means of the measuring device lies outside a definable range in at least one measurement.

2. The method according to claim 1, wherein if the LED modules (1) have more than two LEDs (2-1 . . . 2-4) then the method steps are applied to all possible pairs of LEDs (2-1 . . . 2-4).

3. The method according to claim 1, wherein if the LED modules (1) have more than one pair of LEDs (2-1 . . . 2-4), then two or more optical waveguides (7-1; 7-2) are used for the optical connection of in each case two LEDs.

4. The method according to claim 1, wherein an ICT adapter (5) is used for the connection of LEDs (2-1 . . . 2-4) arranged on a printed circuit board (3) to the at least one power source (11-1; 11-2) and to the at least one measuring device (12-1; 12-2) so as to contact measurement points (9-1 . . . 9-5) and/or solder points of the LEDs and so as to produce the optical connection by means of the optical waveguide (7; 7-1, 7-2).

5. The method according to claim 1, wherein the two ends of the optical waveguide (7; 7-1. 7-2) are brought in a centered manner into the vicinity of the electro-optically active regions of the two LEDs (2-1, 2-2; 2-3, 2-4) of the at least one pair of LEDs.

6. The method according to claim 1, wherein current and/or voltage are/is measured by means of the measuring device (12-1, 12-2).

7. An ICT device for inspecting modules (1) of a lighting device containing at least two LEDs (2-1 . . . 2-4) according to the method of claim 1, the ICT device comprising:
ICT adapter means (5), which comprises at least one power source (11-1, 11-2); and
at least one electrical measuring device (12-1; 12-2),
wherein the ICT adapter means comprises at least one optical waveguide (7; 7-1, 7-2) for the optical connection of in each case two LEDs (2-1, 2-2; 2-3, 2-4) and contact-making means (6-1 . . . 6-5) for contacting measurement points (9-1 . . . 9-5) and/or solder points of the LEDs.

8. The ICT device according to claim 7, wherein the at least one optical waveguide is formed as an optical fiber line.

9. The ICT device according to claim 7, wherein the at least one optical waveguide (7) is formed as a light-guiding U-shaped rod.

10. The ICT device according to claim 7, wherein two or more optical waveguides (7-1, 7-2) are provided for LEDs (2-1 . . . 2-4) sitting on a printed circuit board (3).

11. The ICT device according to claim 7, wherein the measuring device (12-1, 12-2) is a current/voltage measuring device.
